(19) United States
(12) Patent Application Publication
(10) Pub. No.: US 2020/0067294 A1
(43) Pub. Date: Feb. 27, 2020

(54) ELECTRICAL CONNECTION BOX

(71) Applicant: Sumitomo Wiring Systems, Ltd., Yokkaichi (JP)

(72) Inventors: Maiko Oda, Yokkaichi (JP); Yoshiki Yanagita, Yokkaichi (JP)

(21) Appl. No.: 16/546,957

(22) Filed: Aug. 21, 2019

(30) Foreign Application Priority Data
Aug. 24, 2018 (JP) 2018-157436

(51) Int. Cl. H02G 3/08; H02G 3/14; B60R 16/023

(52) U.S. Cl. CPC H02G 3/083; H02G 3/14; H05K 9/0049; H02G 3/088; B60R 16/0238

(57) ABSTRACT

Provided is an electrical connection box capable of preventing a short circuit caused by droplets. The electrical connection box is to be provided in a vehicle, and includes an inner box for housing an electrical device for interconnecting a plurality of in-vehicle devices, and an outer box for supporting the inner box on an inner bottom surface, in which the inner bottom surface of the outer box and an outer bottom surface of the inner box are separated and face each other at a predetermined distance that is larger than a sum of heights of droplets adhering to the inner bottom surface and the outer bottom surface from the surfaces to which the droplets adhere.

### CROSS-REFERENCE TO RELATED APPLICATIONS

This application claims priority of Japanese Patent Application No. JP 2018-157436 filed on Aug. 24, 2018, the contents of which are incorporated herein.

### TECHNICAL FIELD

The present disclosure relates to an electrical connection box.

### BACKGROUND

A vehicle is provided with an electrical connection box (see JP 2017-200269A, for example) that interconnects a plurality of in-vehicle devices such as a battery, a lamp, and a motor. An electrical device that interconnects the plurality of in-vehicle devices is housed in the electrical connection box.

### SUMMARY

However, if liquid such as water ingresses between the bottom surface of an outer box and the electrical device, there is a risk that droplets adhering thereto will cause a short circuit between the outer box and the electrical device.

An object of the present disclosure is to provide an electrical connection box capable of preventing a short circuit caused by droplets.

An electrical connection box according to one aspect of the present disclosure is an electrical connection box to be provided in a vehicle, and including an inner box for housing an electrical device for interconnecting a plurality of in-vehicle devices, and an outer box for supporting the inner box on an inner bottom surface, in which the inner bottom surface of the outer box and an outer bottom surface of the inner box are separated and face each other at a predetermined distance that is larger than a sum of heights of droplets adhering to the inner bottom surface and the outer bottom surface from the surfaces to which the droplets adhere.

According to the above configuration, it is possible to prevent a short circuit caused by droplets.

### BRIEF DESCRIPTION OF THE DRAWINGS

FIG. 1 is a block diagram showing a mode of installing an electrical connection box according to Embodiment 1 in a vehicle;

FIG. 2 is an external perspective view of the electrical connection box;

FIG. 3 is a cross-sectional view of the electrical connection box taken along line III-III;

FIG. 4 is an enlarged cross-sectional view of facing portions of an outer box and an inner box; and

FIG. 5 is a cross-sectional view of an electrical connection box according to Embodiment 2.

### DETAILED DESCRIPTION OF PREFERRED EMBODIMENTS

Embodiments of the present disclosure will be listed and described. Also, at least some of the embodiments described below may be combined as appropriate.

An electrical connection box according to one aspect of the present disclosure is an electrical connection box to be provided in a vehicle, and including an inner box for housing an electrical device for interconnecting a plurality of in-vehicle devices, and an outer box for supporting the inner box on an inner bottom surface, in which the inner bottom surface of the outer box and an outer bottom surface of the inner box are separated and face each other at a predetermined distance that is larger than a sum of heights of droplets adhering to the inner bottom surface and the outer bottom surface from the surfaces to which the droplets adhere.

In this aspect, even if droplets of water or the like adhere to the inner bottom surface of the outer box and the outer bottom surface of the inner box, it is possible to prevent the droplets from coming into contact with each other. Thus, it is possible to prevent a short circuit between the outer box and the electrical device caused by droplets adhering to the inner bottom surface of the outer box and the outer bottom surface of the inner box.

In the electrical connection box according to one aspect of the present disclosure, the predetermined distance may be smaller than 1.5 times the sum of the heights of the droplets from the adherence surfaces in the facing portions.

In this aspect, it is possible to reduce size and favorably prevent a short circuit.

In the electrical connection box according to one aspect of the present disclosure, the predetermined distance may be larger than 7.2 mm and smaller than 10 mm.

In this aspect, it is possible to reduce size and favorably prevent a short circuit.

In the electrical connection box according to one aspect of the present disclosure, the predetermined distance may be larger than 7.8 mm and smaller than 9.5 mm.

In this aspect, it is possible to reduce size and more favorably prevent a short circuit.

In the electrical connection box according to one aspect of the present disclosure, the predetermined distance may be larger than 8.3 mm and smaller than 8.7 mm.

In this aspect, it is possible to reduce size and more favorably prevent a short circuit.

The electrical connection box according to one aspect of the present disclosure may be provided with a protruding portion that protrudes from one of the inner bottom surface of the outer box and the outer bottom surface of the inner box and abuts against the other of the inner bottom surface of the outer box and the outer bottom surface of the inner box.

In this aspect, the protruding portion makes it possible to separate the inner bottom surface of the outer box and the outer bottom surface of the inner box from each other.

In the electrical connection box according to one aspect of the present disclosure, the outer box and the inner box may be screwed together in the protruding portion.

In this aspect, the inner box can be fixed to the outer box.

In the electrical connection box according to one aspect of the present disclosure, a bottom wall of the outer box and a bottom wall of the inner box may be each provided with a hole that passes through in a thickness direction.

In this aspect, it is possible to discharge, from the hole, liquid that has ingressed into the inner box and the outer box.

In the electrical connection box according to one aspect of the present disclosure, the inner box may be made of resin.

In this aspect, it is possible to house the electrical device in the inner box in an insulated state, and to reduce weight.

In the electrical connection box according to one aspect of the present disclosure, the inner box may be made of poly(p-phenylene benzobisoxazole), polybutylene terephthalate, or nylon 66.

In this aspect, it is possible to reduce the weight of the inner box.

In the electrical connection box according to one aspect of the present disclosure, the outer box may be made of aluminum or iron.

In this aspect, it is possible for the inner portion of the outer box to be shielded from noise.

Hereinafter, embodiments of the present disclosure will be specifically described with reference to the drawings.

### Embodiment 1

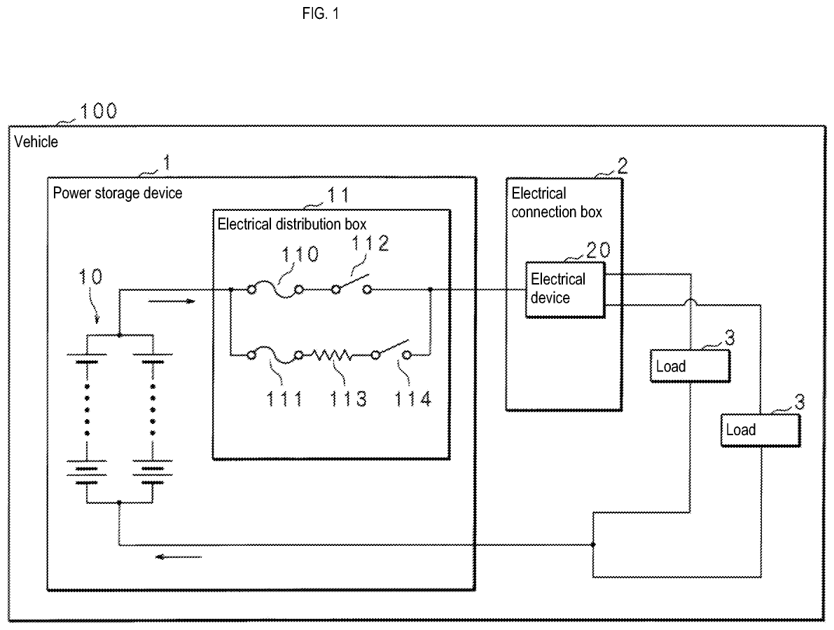

FIG. 1 is a block diagram showing a mode of installing an electrical connection box according to an embodiment in a vehicle. Reference numeral 100 in FIG. 1 denotes a vehicle, and the vehicle 100 includes a power storage device 1, an electrical connection box 2 connected to the power storage device 1 via electric wires such as a wire harness, and a plurality of loads 3 (two in FIG. 1) connected to the electrical connection box 2 via electric wires such as a wire harness.

The power storage device 1 includes a storage battery 10 and an electrical distribution box 11. The storage battery 10 is a lithium battery, for example, and is a secondary battery in which battery cells are connected in series-parallel.

The electrical distribution box 11 is a so-called junction box for distributing power from the storage battery 10 to in-vehicle devices. The electrical distribution box 11 has a plurality of systems for distributing power to in-vehicle devices. Note that, in FIG. 1, only the system for supplying power to the electrical connection box 2 is shown and the other systems are not shown.

Two fuses 110 and 111, a switch 112, a resistor 113, a switch 114, and the like, which constitute one system, are arranged in the housing (not shown) of the electrical distribution box 11, the housing being waterproofed by a sealing member, for example. One end of each of the two fuses 110 and 111 is connected to a cathode of the storage battery 10 in parallel. The other end of the fuse 110 is connected to one end of the switch 112. The other end of the fuse 111 is connected to one end of the switch 114 via the resistor 113. The other ends of the switches 112 and 114 are connected to the electrical connection box 2. The switches 112 and 114 are turned ON and OFF using an ECU (Electronic Control Unit), which is not shown.

The electrical connection box 2 distributes power supplied from the electrical distribution box 11 to supply power to the loads 3 serving as a plurality of in-vehicle devices. The electrical connection box 2 includes an electrical device 20 connected to the switches 112 and 114 and the loads 3 by electric wires such as a wire harness. The electrical device 20 includes a fuse, a bus bar, and the like. Examples of the loads 3 include a lamp, a wiper, and a motor. One end of each load 3 is connected to the electrical device 20, and the other end is connected to an anode of the storage battery 10.

In the above-described configuration, as shown by arrows in FIG. 1, electric current flows from the cathode of the storage battery 10 to the loads 3 via the electrical distribution box 11 and the electrical connection box 2, and electric current flowing through the loads 3 flows to the anode of the storage battery 10.

Here, when the loads 3 are driven, the switch 114 is turned ON so that electric current flows to the resistor 113 side, and inrush current is reduced. Then, the switch 114 is turned OFF, and the switch 112 is turned ON to supply electric current to the loads 3. Due to the fuses 110 and 111 being provided, supply of power to the electrical connection box 2 and the loads 3 can be shut off if electric current with a predetermined electric current value or more flows.

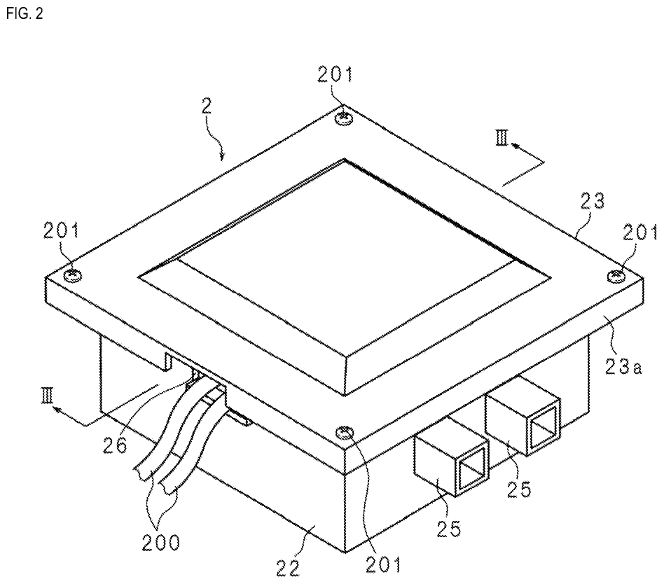

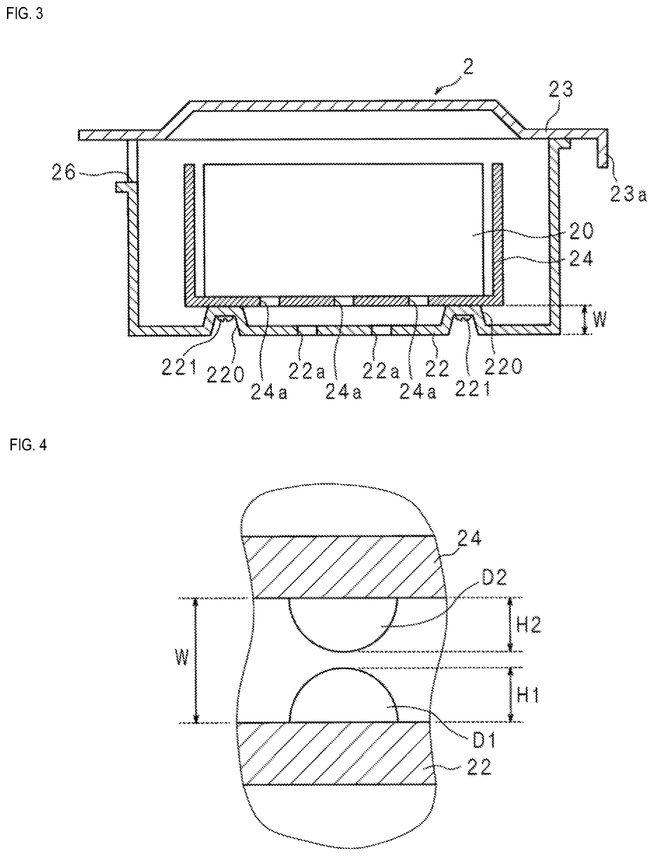

FIG. 2 is an external perspective view of the electrical connection box 2. FIG. 3 is a cross-sectional view of the electrical connection box 2 taken along line III-III. The electrical connection box 2 includes a rectangular parallelepiped outer box 22 with one side being open, and a lid 23 for closing the opening of the outer box 22. The electrical connection box 2 is installed in the vehicle 100 with the lid 23 facing upward.

The outer box 22 is made of a metal such as aluminum or iron, for example. Accordingly, the inner portion of the outer box 22 can be shielded from noise, and the weight of the outer box 22 can be reduced. Two connectors 25 protrude from one of side walls of the outer box 22, and the electrical device 20 is connected to electric wires through the connectors 25. The number of connectors 25 is not limited to that shown in FIG. 2, and it is sufficient to provide the connectors 25 in correspondence with the number of connecting electric wires.

Another side wall of the outer box 22 is provided with an insertion port 26 into which the wire harness 200 is inserted. The insertion port 26 is provided on the upper side of the other side wall, and has a rectangular shape that is longer in the horizontal direction. Note that the wire harness 200 is not shown in FIG. 3.

The lid 23 has a rectangular plate shape, and has an outer size that is larger than the outer size of the opening of the outer box 22. An extending portion 23a extending in a downward direction is provided in portions of a peripheral edge portion of the lid 23 other than the central portion of one side. The lid 23 is attached so as to cover the entire opening of the outer box 22, with the central portion of the one side having no extending portion 23a corresponding to the insertion port 26 and the lower surface of the lid 23 placed on the peripheral edge portion of the opening of the outer box 22, and by screwing down the four corners using screws 201. The upper surface of the lid 23 is raised except for the peripheral edge portion. Accordingly, if water flows from the upper side, the lid 23 enables the water to flow to the outer side.

As shown in FIG. 3, the inner bottom surface of the outer box 22 is provided with two protruding portions 220 that are raised on the opening side. Note that the number of protruding portions 220 is not limited to that shown in FIG. 3.

Also, the bottom wall of the outer box 22 is provided with a plurality of holes 22a passing through the bottom wall in the thickness direction. Liquid inside the electrical connection box 2 is discharged to the outside through the holes 22a. The liquid is water, for example, and there is a possibility that liquid will ingress through the insertion port 26.

One side of the inner box 24 is open, and the electrical devices 20 such as a fuse and a bus bar are housed in the inner box 24. The inner box 24 is housed in the outer box 22 such that the outer bottom surface of the inner box 24 abuts against the protruding portions 220 of the inner bottom surface of the outer box 22 and the outer bottom surface of the inner box 24 faces the inner bottom surface of the outer box 22. The protruding portions 220 make it possible to separate the inner bottom surface of the outer box 22 and the outer bottom surface of the bottom wall of the inner box 24 from each other.

The inner box 24 is made of resin, and is made of poly(p-phenylene benzobisoxazole), polybutylene terephthalate, nylon 66 (PA (Polyamide) 66), or a PA66/PPE (Polyphenyleneether) alloy, for example. The bottom wall of the inner box 24 is provided with a plurality of holes 24a passing through the bottom wall. Liquid ingressing into the inner box 24 can be discharged to the outside through the holes 24a.

The bottom wall of the inner box 24 and the bottom wall of the outer box 22 are screwed together in the protruding portions 220 using screws 221 from the outer side of the outer box 22. This makes it possible to fix the inner box 24 to the outer box 22.

The outer bottom surface of the inner box 24 and the inner bottom surface of the outer box 22 are separated from each other at a predetermined distance W. In the case where droplets adhere to facing portions of the inner bottom surface of the outer box 22 and the outer bottom surface of the inner box 24, the predetermined distance W is a distance by which the droplets will not contact each other.

FIG. 4 is an enlarged cross-sectional view of the facing portions of the outer box 22 and the inner box 24. FIG. 4 shows a case where droplets adhere to the outer bottom surface of the inner box 24 and the inner bottom surface of the outer box 22. A droplet D1 adheres to the outer box 22, and a droplet D2 adheres to the inner box 24. A height of the droplet D1 from the adherence surface is H1, and a height of the droplet D2 from the adherence surface is H2. The heights H1 and H2 are calculated using a known method based on the surface tension and density of the liquid that adheres thereto, surface roughness, material and contact angle of the adherence portions, gravitational acceleration, and the like.

As shown in FIG. 4, the predetermined distance W is larger than the sum of the heights H1 and H2 of the droplets D1 and D2. Here, for example, if the liquid is sea water, the outer box 22 is made of aluminum, and the inner box 24 is made of poly(p-phenylene benzobisoxazole), the height H1 is 2.96 mm, and the height H2 is 4.16 mm, for example.

The predetermined distance W is preferably smaller than 1.5 times the sum (=7.12 mm) of the heights of the droplets from the adherence surfaces in the facing portions. Also, the predetermined distance W is preferably larger than 7.2 mm and smaller than 10 mm. The predetermined distance W is more preferably larger than 7.8 mm and smaller than 9.5 mm. The predetermined distance W is particularly preferably larger than 8.3 mm and smaller than 8.7 mm. The predetermined distance W is set to 8.5 mm, for example.

Here, the holes 24a of the inner box 24 and the holes 22a of the outer box 22 are provided at positions at which the holes 24a and the holes 22a do not overlap each other. This makes it possible to favorably prevent contact between droplets adhering to facing portions of the bottom surface of the outer box 22 and the outer surface of the bottom wall of the inner box 24.

According to the above-described configuration, even if droplets of water or the like adhere to facing portions of the inner bottom surface of the outer box 22 and the outer bottom surface of the inner box 24, it is possible to prevent contact between the droplets. This makes it possible to prevent contact between the inner box 24 and the outer box 22 via the droplets. Thus, it is possible to prevent a short circuit between the outer box 22 and the electrical device 20 caused by droplets adhering to the inner bottom surface of the outer box 22 and the outer bottom surface of the electrical device 20. Also, as a result of making the predetermined distance W smaller than 1.5 times the sum (=7.12 mm) of the heights of the droplets, the size of the electrical connection box 2 can be reduced.

Also, as a result of the inner box 24 being made of resin, the electrical device 20 can be housed therein in an insulated state, and the weight of the inner box 24 can be reduced. Also, as a result of the outer box 22 being made of aluminum or iron, the outside can be shielded from noise. Also, as a result of the outer box 22 being made of aluminum, the weight of the outer box 22 can be reduced.

### Embodiment 2

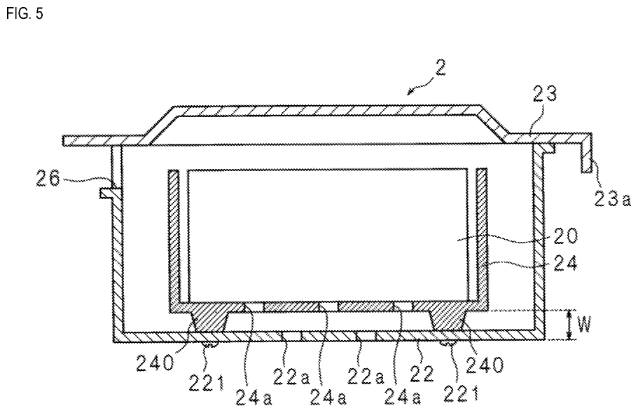

An electrical connection box according to Embodiment 2 is different from the electrical connection box according to Embodiment 1 in the shapes of the outer box 22 and the inner box 24. FIG. 5 is a cross-sectional view of an electrical connection box 2 according to Embodiment 2. Constituent elements of an electrical connection box according to Embodiment 2 that are similar to those of Embodiment 1 will be given the same reference numerals, and a detailed description thereof will be omitted.

In the electrical connection box 2 according to Embodiment 2, an outer bottom surface of the inner box 24 is provided with two protruding portions 240 protruding from the outer bottom surface of the inner box 24. Note that the number of protruding portions 240 is not limited to the two shown in FIG. 5.

The inner box 24 is screwed down using screws 221 from the outer side of the outer box 22 at the positions of the protruding portions 240, with the protruding portions 240 in contact with the inner bottom surface of the outer box 22. This makes it possible to fix the inner box 24 to the outer box 22. Also, the protruding portions 240 make it possible to separate the inner bottom surface of the outer box 22 and the outer bottom surface of the inner box 24 from each other at a predetermined distance W. The predetermined distance W is set in a manner similar to that of Embodiment 1.

According to the above-described configuration, similarly to Embodiment 1, it is possible to prevent a short circuit between the outer box 22 and the electrical device 20 caused by droplets of water or the like adhering to the bottom surface and the surface facing the bottom surface, and to avoid an increase in the size of the electrical connection box 2.

Note that, in Embodiments 1 and 2, a configuration may be adopted in which a spacer is provided between the outer bottom surface of the inner box 24 and the inner bottom surface of the outer box 22, instead of the configuration in which the protruding portions 220 and the protruding portions 240 are provided.

The embodiments that were disclosed here are considered in all respects to be illustrative and not restrictive. The scope of the present disclosure is defined by the appended claims and not by the above description, and all changes that come within the meaning and range of equivalency of the claims are intended to be embraced therein.

What is claimed is:

1. An electrical connection box to be provided in a vehicle, the electrical connection box comprising:
an inner box for housing an electrical device for interconnecting a plurality of in-vehicle devices; and
an outer box for supporting the inner box on an inner bottom surface,
wherein the inner bottom surface of the outer box and an outer bottom surface of the inner box are separated and face each other at a predetermined distance that is larger than a sum of heights of droplets adhering to the inner bottom surface and the outer bottom surface from the surfaces to which the droplets adhere.

2. The electrical connection box according to claim 1, wherein the predetermined distance is smaller than 1.5 times the sum of the heights of the droplets from the adherence surfaces in the facing portions.

3. The electrical connection box according to claim 1, wherein the predetermined distance is larger than 7.2 mm and smaller than 10 mm.

4. The electrical connection box according to claim 1, wherein the predetermined distance is larger than 7.8 mm and smaller than 9.5 mm.

5. The electrical connection box according to claim 1, wherein the predetermined distance is larger than 8.3 mm and smaller than 8.7 mm.

6. The electrical connection box according to claim 1, wherein the electrical connection box is provided with a protruding portion that protrudes from one of the inner bottom surface of the outer box and the outer bottom surface of the inner box and abuts against the other of the inner bottom surface of the outer box and the outer bottom surface of the inner box.

7. The electrical connection box according to claim 6, wherein the outer box and the inner box are screwed together in the protruding portion.

8. The electrical connection box according to claim 1, wherein a bottom wall of the outer box and a bottom wall of the inner box are each provided with a hole that passes through in a thickness direction.

9. The electrical connection box according to claim 1, wherein the inner box is made of resin.

10. The electrical connection box according to claim 9, wherein the inner box is made of poly(p-phenylene benzobisoxazole), polybutylene terephthalate, or nylon 66.

11. The electrical connection box according to claim 1, wherein the outer box is made of aluminum or iron.
